(19) United States
(12) Patent Application Publication
(10) Pub. No.: US 2025/0096080 A1
(43) Pub. Date: Mar. 20, 2025

(54) SEMICONDUCTOR DEVICE

(71) Applicant: FUJI ELECTRIC CO., LTD., Kawasaki-shi (JP)

(72) Inventors: Shun HARASHIMA, Matsumoto-city (JP); Nobuya KOIKE, Maebashi-city (JP)

(73) Assignee: FUJI ELECTRIC CO., LTD., Kawasaki-shi (JP)

(21) Appl. No.: 18/820,215

(22) Filed: Aug. 29, 2024

(30) Foreign Application Priority Data
Sep. 14, 2023 (JP) 2023-149278

(51) Int. Cl. H01L 23/495; H01L 23/00; H01L 23/04; H01L 23/31; H01L 25/07

(52) U.S. Cl. CPC H01L 23/49548; H01L 23/041; H01L 23/3107; H01L 23/49562; H01L 24/48; H01L 25/072; H01L 24/45; H01L 2224/45224; H01L 2224/45239; H01L 2224/45244; H01L 2224/45247; H01L 2224/48177; H01L 2924/13055; H01L 2924/13091; H01L 2924/3511; H01L 2924/3512

(57) ABSTRACT

A semiconductor device includes a wire electrically connected to a semiconductor chip, a terminal having top and bottom surfaces opposite to each other and a plurality of side surfaces between the top and bottom surfaces, a resin case, and a sealing material. The terminal has a wire connection area on the top surface thereof to which the wire is connected, a terminal coupling portion having a step formed by one of the plurality of side surfaces and a flat surface parallel to the top surface, to form a concave portion therein, and a protrusion on the top surface protruding away from the top surface, adjacent to the concave portion. The resin case is in contact with the bottom surface of the terminal and has a case coupling portion coupled with and extending upward along the terminal coupling portion to have a height above the protrusion of the terminal.

### CROSS-REFERENCE TO RELATED APPLICATION

This application is based upon and claims the benefit of priority of the prior Japanese Patent Application No. 2023-149278, filed on Sep. 14, 2023, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a board, a lead frame, a case with which the lead frame is integrally formed and in which the board is stored, and sealing material sealing the case. In addition, the board and the lead frame are connected to each other by a wire in the case (for example, see the following literatures).
Japanese Laid-open Patent Publication No. 2000-332179
International Publication Pamphlet No. WO 2018/047659
Japanese Laid-open Utility Model Publication No. H07-010947
Japanese Laid-open Patent Publication No. 2016-111028
Japanese Laid-open Patent Publication No. 2019-067885
Japanese Laid-open Patent Publication No. 2004-134518
Japanese Laid-open Patent Publication No. 2000-208655
Japanese Laid-open Patent Publication No. 2001-332371

### SUMMARY OF THE INVENTION

In one aspect of the embodiments, there is provided a semiconductor device, including: a semiconductor chip; a wire electrically connected to the semiconductor chip; a terminal having a top surface and a bottom surface opposite to each other, and a plurality of side surfaces between the top surface and the bottom surface, the terminal having, at one side of one end thereof, a wire connection area on the top surface of the terminal, to which the wire is connected, a terminal coupling portion having a step formed by one of the plurality of side surfaces and a flat surface that is parallel to the top surface of the terminal, to form a concave portion therein at a side of the top surface of the terminal, and a protrusion on the top surface protruding in a direction away from the top surface and being located adjacent to the concave portion between the concave portion and the wire connection area; a resin case that is in contact with the bottom surface of the terminal and has a case coupling portion coupled with the terminal coupling portion such that the case coupling portion is in contact with the one of the plurality of side surfaces and the concave portion of the terminal and extends upward along the terminal coupling portion to have a height above the protrusion of the terminal, the wire connection area, the concave portion and the protrusion being located inside the resin case; and a sealing material sealing the case coupling portion and the wire connection area inside the resin case.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a side sectional view of a semiconductor device according to a first embodiment;

FIG. 2 is a plan view of a main portion of the semiconductor device according to the first embodiment (sealing material is not illustrated);

FIG. 3 is a plan view of a main portion of a connection terminal included in the semiconductor device according to the first embodiment (the sealing material is not illustrated);

FIG. 4 is a side sectional view of the main portion of the connection terminal included in the semiconductor device according to the first embodiment;

FIG. 5 is a side sectional view of the main portion of connection terminal included in the semiconductor device according to the first embodiment;

FIG. 6 is a side sectional view of a connection terminal included in a semiconductor device according to a reference example;

FIG. 7 is a flowchart illustrating a manufacturing method of the semiconductor device according to the first embodiment;

FIGS. 8A and 8B are each a first side sectional view illustrating a work process performed on a conductive member according to the first embodiment;

FIGS. 9A to 9C are each a second side sectional view illustrating the work process performed on the conductive member according to the first embodiment;

FIG. 10 is a plan view of a connection terminal according to the first embodiment (modifications);

FIGS. 11A to 11C are each a side sectional view of a connection terminal according to the first embodiment (modifications);

FIG. 12 is a plan view of a main portion of a connection terminal included in a semiconductor device according to a second embodiment (sealing material is not illustrated);

FIG. 13 is a side sectional view of the main portion of the connection terminal included in the semiconductor device according to the second embodiment;

FIG. 14 is a plan view of a main portion of a connection terminal included in a semiconductor device according to a third embodiment (sealing material is not illustrated);

FIG. 15 is a side sectional view of the main portion of the connection terminal included in the semiconductor device according to the third embodiment;

FIG. 16 is a plan view of a main portion of a connection terminal included in a semiconductor device according to a fourth embodiment (sealing material is not illustrated); and

FIG. 17 is a side sectional view of the main portion of the connection terminal included in the semiconductor device according to the fourth embodiment.

### DETAILED DESCRIPTION OF THE INVENTION

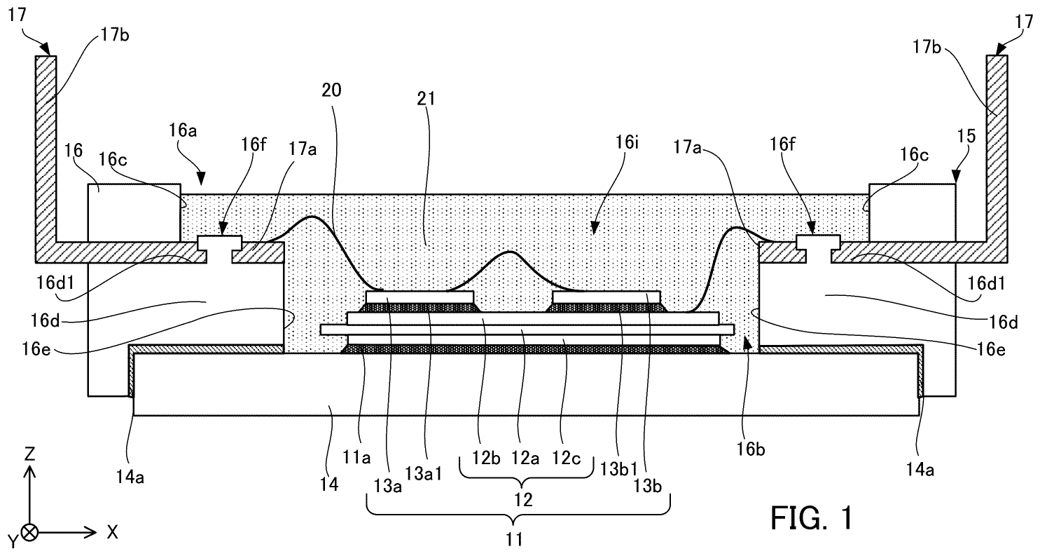

Hereinafter, embodiments will be described with reference to the accompanying drawings. In the following description, regarding a semiconductor device 10 in FIG. 1, terms “front surface” and “top surface” each express a surface facing in the +Z direction. Likewise, regarding the semiconductor device 10 in FIG. 1, a term “up” expresses the +Z direction. Regarding the semiconductor device 10 in FIG. 1, terms “rear surface” and “bottom surface” each express a surface facing in the −Z direction. Likewise, regarding the semiconductor device 10 in FIG. 1, a term “down” expresses the −Z direction. Regarding the semiconductor device 10 in FIG. 1, a term “side surface” expresses a surface connecting “front surface” or “top surface” and “rear surface” or “bottom surface”. For example, regarding the semiconductor device 10 in FIG. 1, the term “side surface” expresses a surface facing the ±X directions or the ±Y directions. In all the other drawings, the above terms also mean their respective directions. The terms “front surface”, “top surface”, “up”, “rear surface”, “bottom surface”, “down”, and “side surface” are simply used as convenient expressions to determine relative positional relationships and do not limit the technical ideas of the embodiments. For example, the terms “up” and “down” may mean directions other than the vertical directions with respect to the ground. That is, the directions expressed by “up” and “down” are not limited to the directions relating to the gravitational force. In addition, in the following description, when a component contained in a material represents 80 vol % or more of the material, this component will be referred to as “main component” of the material. In addition, in the following description, phrases “approximately parallel” and “approximately horizontal direction” are used when the angle formed by two objects is between 1700 and 1900, inclusive. Phrases “approximately right angle” and “approximately vertical direction” are used when the angle formed by two objects is between 85° and 95°, inclusive.

### First Embodiment

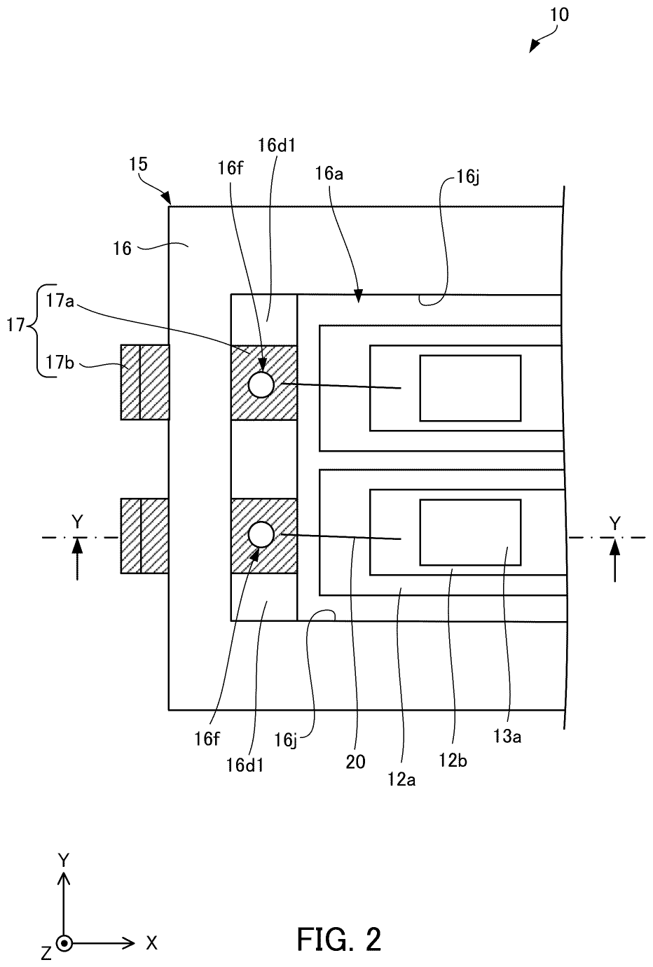

A semiconductor device according to a first embodiment will be described with reference to FIGS. 1 and 2. FIG. 1 is a side sectional view of the semiconductor device according to the first embodiment. FIG. 2 is a plan view of a main portion of the semiconductor device according to the first embodiment (sealing material is not illustrated). FIG. 1 is a sectional view, taken along a dashed-dotted line Y-Y in FIG. 2. In FIG. 2, the illustration of sealing material 21 is omitted. FIG. 2 is a plan view of an area around connection terminals 17 in FIG. 1.

As illustrated in FIGS. 1 and 2, this semiconductor device 10 includes a semiconductor unit 11, a heat dissipation plate 14 having a front surface on which the semiconductor unit 11 is disposed and having a rectangular shape in plan view, a case 15 disposed at the outer edge portion of the heat dissipation plate 14 and storing the semiconductor unit 11, and the sealing material 21 sealing the case 15. The semiconductor unit 11 includes an insulated circuit board 12, and semiconductor chips 13a and 13b disposed on the front surface of the insulated circuit board 12 via bonding material.

The insulated circuit board 12 includes insulating plates 12a, a plurality of circuit patterns 12b, each of which is formed on the front surface of a corresponding one of the insulating plates 12a, and metal plates 12c, each of which is formed on the rear surface of a corresponding one of the insulating plates 12a. The insulating plates 12a and the metal plates 12c each have a rectangular shape in plan view. The individual insulating plate 12a and the individual metal plate 12c may have rounded or chamfered corner portions. The individual metal plate 12c is smaller in size than the corresponding insulating plate 12a in plan view, and is formed on the inner side of this insulating plate 12a.

For example, an organic insulating layer, an insulating resin, or a ceramic board may be used as the individual insulating plate 12a. The organic insulating layer is made of a combination of a resin having a low thermal resistance and a material having a high thermal conductivity. The resin is, for example, epoxy resin or a liquid crystal polymer insulating resin. The material is, for example, boron nitride, aluminum oxide, or silicon oxide. The insulating resin is, for example, a paper phenol board, a paper epoxy board, a glass composite board, or a glass epoxy board. The ceramic board is made of a ceramic material having a good thermal conductivity. The ceramic material contains aluminum oxide, aluminum nitride, or silicon nitride as its main component, for example. The individual insulating plate 12a has a rectangular shape in plan view.

The plurality of circuit patterns 12b are each formed on the entire surface of a corresponding one of the insulating plates 12a, excepting the edge portions thereof. Preferably, in plan view, end portions of each of the plurality of circuit patterns 12b, the end portions facing the outer periphery of a corresponding one of the insulating plates 12a, overlap the outer periphery end portions of a corresponding one of the metal plates 12c. Thus, regarding the insulated circuit board 12, the stress balance between the plurality of circuit patterns 12b formed on the front surface of the insulating plates 12a and the metal plates formed on the rear surface of the insulating plates 12a is maintained. Occurrence of an excessive warpage and damage such as a crack in any one of the insulating plates 12a is reduced. The individual circuit pattern 12b is made of a material having an excellent electrical conductivity. Examples of the material include copper, aluminum, and an alloy containing at least one of these kinds of elements. The individual circuit pattern 12b may be plated with a material having an excellent corrosion resistance. This material is, for example, nickel, a nickel-phosphorus alloy, or a nickel-boron alloy. The thickness of the plating film is preferably 1 μm or greater, more preferably, 5 μm or greater. The circuit patterns 12b on the insulating plates 12a may be formed by forming a metal plate on the front surface of the individual insulating plate 12a and by etching this metal plate, for example. Alternatively, the circuit patterns 12b, which have been cut out from a metal plate, may be attached to the front surface of the insulating plates 12a by applying pressure. The individual circuit pattern 12b is only an example. For example, the number, shape and size of these circuit patterns may be suitably set as needed.

The individual metal plate 12c is made of a metal material having an excellent thermal conductivity. Examples of the metal material include copper, aluminum, and an alloy containing at least one of these kinds of elements. The surface of the individual metal plate 12c may be plated to improve its corrosion resistance. For example, the material used for this plating is nickel, a nickel-phosphorus alloy, or a nickel-boron alloy.

For example, the insulated circuit board 12 having the above-described construction may be a direct copper bonding (DCB) board or an active metal brazed (AMB) board. With this insulated circuit board 12, the heat generated by the semiconductor chips 13a and 13b, which will be described below, is transferred to the rear surface of the insulated circuit board 12 via the circuit patterns 12b, the insulating plates 12a, and the metal plates 12c, and is consequently dissipated.

The semiconductor chips 13a and 13b are each a power device made of silicon, silicon carbide, or gallium nitride. The individual semiconductor chip 13a includes a switching element, which for is, example, a power metal-oxide-semiconductor field-effect transistor (MOSFET) or an insulated gate bipolar transistor (IGBT). For example, the individual semiconductor chip 13a has, on its rear surface, an input electrode as a main electrode (a drain electrode if the switching element is a power MOSFET and a collector electrode if the switching element is an IGBT), and has, on its front surface, a control electrode (a gate electrode) and an output electrode as a main electrode (a source electrode if the switching element is a power MOSFET and an emitter electrode if the switching element is an IGBT).

The individual semiconductor chip 13b includes a diode element, which may be, for example, a Schottky barrier diode (SBD) or a P-intrinsic-N (PiN) diode as a freewheeling diode (FWD). The individual semiconductor chip 13b has, on its rear surface, an output electrode as a main electrode (a cathode electrode), and has, on its front surface, an input electrode as a main electrode (an anode electrode).

The rear surface of each of the semiconductor chips 13a and 13b is bonded to a corresponding one of the circuit patterns 12b via bonding material 13a1 and 13b1. The bonding material 13a1 and 13b1 are solder or sintered material. The solder is lead-free solder containing a predetermined alloy as its main component. The predetermined alloy is, for example, at least one of a tin-silver-copper alloy, a tin-zinc-bismuth alloy, a tin-copper alloy, a tin-silver-indium-bismuth alloy, and a tin-antimony alloy. The soler may contain an additive. The additive is, for example, nickel, germanium, cobalt, or silicon. The sintered material used when the bonding is performed by sintering is, for example, powder of silver, iron, copper, aluminum, titanium, nickel, tungsten, or molybdenum. As an example, FIG. 1 illustrates a case in which a pair of semiconductor chips 13a and 13b are disposed on the insulated circuit board 12. The embodiment is not limited to this example. A plurality of pairs of semiconductor chips may be suitably disposed based on the design.

Instead of the semiconductor chip 13a or 13b, a semiconductor chip including a reverse-conducting (RC)-IGBT as a switching element may be disposed. The RC-IGBT is obtained by forming an IGBT and an FWD in anti-parallel on one chip. For example, the semiconductor chip has, on its rear surface, an input electrode as a main electrode (a collector electrode), and has, on its front surface, a control electrode (a gate electrode) and an output electrode as a main electrode (an emitter electrode).

Instead of the semiconductor chip 13a or 13b, a semiconductor chip including a power MOSFET as a switching element made of silicon carbide may be disposed. The body diode of the power MOSFET may function as an FWD. The semiconductor chip has, on its rear surface, an input electrode as a main electrode (a drain electrode), and has, on its front surface, a control electrode (a gate electrode) and an output electrode as a main electrode (a source electrode).

The heat dissipation plate 14 has a rectangular flat plate shape in plan view. The heat dissipation plate 14 is made of a metal material having an excellent thermal conductivity. For example, the material is aluminum, iron, silver, copper, or an alloy containing at least one of these kinds of elements. For example, the alloy is a metal composite of aluminum and silicon carbide (Al—SiC) or a metal composite of magnesium and silicon carbide (Mg—SiC). For example, the surface of the heat dissipation plate 14 may be plated to improve its corrosion resistance. The plating material is, for example, nickel, a nickel-phosphorus alloy, or a nickel-boron alloy. A cooling unit (not illustrated) may be attached to the rear surface of the case 15 including the heat dissipation plate 14 via a thermally conductive member. The thermally conductive member is a thermal interface material (TIM). The TIM is, for example, a generic term for various kinds of materials such as thermally conductive grease, elastomer sheet, room temperature vulcanization (RTV) rubber, gel, phase-change material, solder, and silver solder. In this way, the heat dissipation of the semiconductor device 10 is improved. The cooling unit in this case is made of a metal material having an excellent thermal conductivity, for example. The metal material is, for example, aluminum, iron, silver, copper, or an alloy containing at least one these kinds of elements. The heat dissipation plate 14 may have a different shape other than a flat plate shape. The rear surface of the heat dissipation plate 14 (a main surface opposite to the main surface where the semiconductor unit 11 is disposed) may have, for example, concave and convex portions. The cooling unit is, for example, a heatsink including at least one fin or a water-cooled cooling device. The heat dissipation plate 14 may be formed integrally with the cooling unit described above.

The case 15 includes a frame portion 16 and connection terminals 17 attached to the frame portion 16. In plan view, the frame portion 16 has a rectangular frame shape surrounding a storage region 16i. The storage region 16i is a region that is open from an upper opening portion 16a near the front surface of the case 15 to a lower opening portion 16b near the rear surface of the case 15. The upper opening portion 16a may have a larger area than that of the lower opening portion 16b. The rear surface of the frame portion 16 has a step portion to which the heat dissipation plate 14 is attached.

Upper inner walls 16c surround the upper portion of the storage region 16i, and constitute the upper opening portion 16a communicating with the lower opening portion 16b. Lower inner walls 16e surround the lower portion of the storage region 16i, and constitute the lower opening portion 16b communicating with the upper opening portion 16a. The frame portion 16 has a placement portion 16d near each of its short sides in plan view, and each placement portion 16d is located between the corresponding upper inner wall 16c and the corresponding lower inner wall 16e. The upper inner walls 16c are disposed approximately perpendicularly to the front surface of the frame portion 16. The placement portions 16d extend and are disposed approximately perpendicularly to the upper inner walls 16c. The lower inner walls 16e are disposed approximately perpendicularly to the placement portions 16d.

As seen from the above description, in plan view, the short-side lower inner walls 16e protrude toward the inner side of the storage region 16i more than the upper inner walls 16c by their respective placement portions 16d. Placement surfaces 16d1 are each the top surface of a +Z direction end portion of their respective placement portions 16d. On each of the placement surfaces 16d1, an inner wiring portion 17a of a connection terminal 17 is disposed. To fix the inner wiring portions 17a to their respective placement surfaces 16d1, fixing portions (case coupling portion) 16f are formed. Each of the fixing portions 16f is formed in an approximately center portion of the ±Y direction width of a corresponding one of the inner wiring portions 17a. The fixing portions 16f each have an approximately circular shape in plan view. Details of these fixing portions 16f will be described below.

In addition, inner walls 16j are disposed at the long sides of the frame portion 16 in plan view. The inner walls 16j extend approximately perpendicularly and downward from the front surface of the frame portion 16. Thus, the upper opening portion 16a and the lower opening portion 16b are enclosed by the short-side upper inner walls 16c, the lower inner walls 16e, and the long-side inner walls 16j. Depending on the design of the semiconductor device 10, the short-side upper inner walls 16c may be formed without the placement portions 16d. In this case, the upper inner walls 16c may be formed to extend straight approximately perpendicularly to and downward from the front surface of the frame portion 16 to the rear surface of the frame portion 16.

The frame portion 16 is formed by injection molding using a thermoplastic resin containing a filler. Examples of this resin include a polyphenylene sulfide (PPS) resin, a polybutylene terephthalate (PBT) resin, and a polyamide (PA) resin. The filler is made of, for example, glass fiber, glass bead, calcium carbide, talc, magnesium oxide, or aluminum hydroxide. In particular, a PPS resin containing any one of the above fillers is used for the frame portion 16.

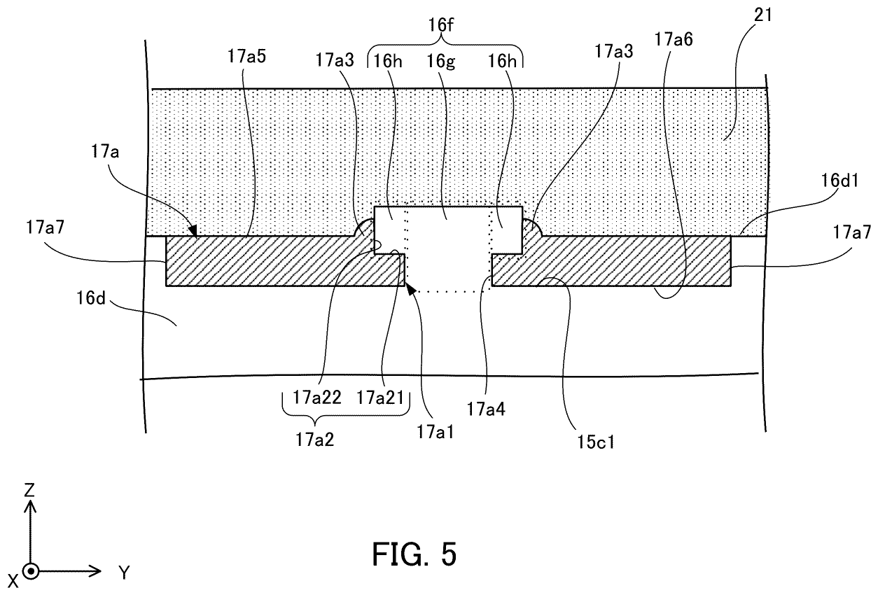

The individual connection terminal 17 is an example of a terminal, has a flat plate shape, and has an L shape in side view. The connection terminals 17 are formed integrally with the frame portion 16. The individual connection terminal 17 includes an inner wiring portion 17a and an outer wiring portion 17b formed approximately perpendicular to an end portion of the inner wiring portion 17a. The inner wiring portion 17a is embedded in the placement surface 16d1 of the corresponding placement portion 16d included in the frame portion 16 in parallel to the front surface of the frame portion 16, and extends to the outside from the frame portion 16. One end portion of the individual inner wiring portion 17a (an end portion located in the direction of the storage region 16i) extends from the corresponding upper inner wall 16c perpendicularly to this upper inner wall 16c toward the storage region 16i. The front surface of this one end portion appears on the corresponding placement portion 16d. In addition, a fixing hole (terminal coupling portion) 17a1 is formed in each of the inner wiring portions 17a (see FIG. 5).

The individual outer wiring portion 17b has one end portion connected integrally with one end of the corresponding inner wiring portion 17a outside the frame portion 16. The outer wiring portion 17b is approximately parallel to the corresponding upper inner wall 16c of the frame portion 16, and extends in the +Z direction. Details of these connection terminals 17 will be described below.

The individual connection terminal 17 is made of a material having an excellent electrical conductivity. This material is, for example, copper, aluminum, or an alloy containing at least one of these kinds of elements. Overall, the individual connection terminal 17 has the same thickness. The connection terminals 17 may be plated with a material having an excellent corrosion resistance. The material is, for example, aluminum, nickel, titanium, chromium, molybdenum, tantalum, niobium, tungsten, vanadium, bismuth, zirconium, hafnium, gold, silver, platinum, palladium, or an alloy containing at least one these kinds of elements.

The rear surface of the frame portion 16 of the case 15, the rear surface being located around the lower opening portion 16b, is bonded to the outer periphery of the front surface of the heat dissipation plate 14, to which the semiconductor unit 11 has been bonded, via adhesive 14a. The semiconductor unit 11 is consequently stored in the storage region 16i of the frame portion 16. Although not illustrated, a cover may be bonded to the front surface of the frame portion 16, the front surface being located around the upper opening portion 16a, by adhesive. The adhesive 14a is, for example, thermosetting resin-based adhesive or organic-based adhesive. The main component of the thermosetting resin-based adhesive is, for example, epoxy resin or phenol resin. The organic-based adhesive is, for example, elastomer-based adhesive containing silicone rubber or chloroprene rubber as its main component.

Bonding areas of the inner wiring portions 17a of the connection terminals 17 of the case 15, the circuit patterns 12b of the insulated circuit board 12, and the semiconductor chips 13a and 13b are electrically connected by wiring members. For example, the wiring members may be bonding wires 20 illustrated in FIG. 1. The individual bonding wire 20 is made of a material having an excellent electrical conductivity. The material is, for example, gold, silver, copper, aluminum, or an alloy containing at least one of these kinds of elements. Alternatively, a lead frame may be used as these wiring members.

The sealing material 21 is injected into the storage region 16i of the frame portion 16, so as to seal the semiconductor unit 11, the bonding wires 20, and the inner wiring portions 17a of the connection terminals 17. The sealing material 21 may be, for example, a thermosetting resin to which a filler has been added. The modulus of elasticity of the material is between 3 GPa and 25 GPa, inclusive. In addition, the coefficient of linear expansion is between 7×10⁻⁶/K and 30×10⁻⁶/K, inclusive. Examples of the thermosetting resin include epoxy resin, phenol resin, maleimide resin, and polyester resin. The filler may be an insulating ceramic material having a high thermal conductivity. Examples of the filler include silicon oxide, aluminum oxide, boron nitride, and aluminum nitride. The amount of filler contained is between 10% by volume and 70% by volume of the sealing material 21.

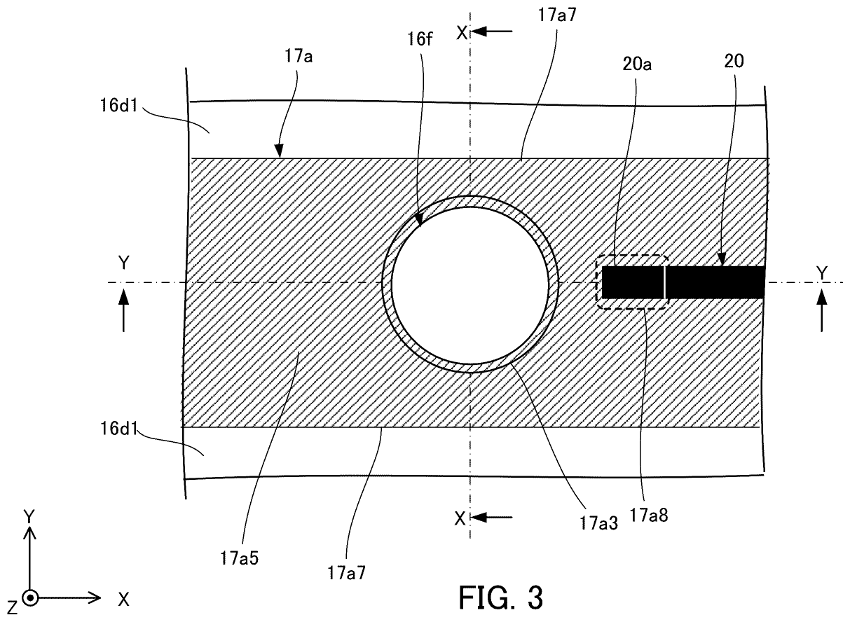

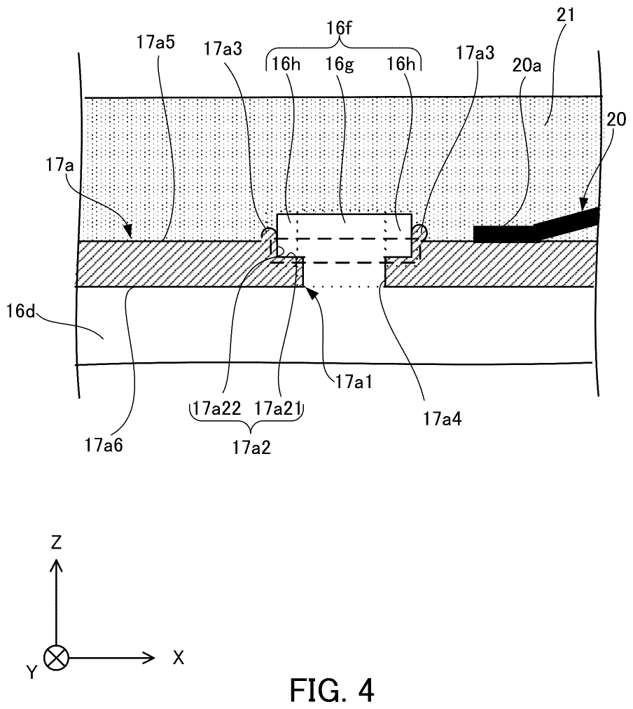

Next, the connection terminals 17 will be described in detail with reference to FIGS. 3 to 5. FIG. 3 is a plan view of a main portion of a connection terminal included in the semiconductor device according to the first embodiment. FIGS. 4 and 5 are side sectional views of the main portion of the connection terminal included in the semiconductor device according to the first embodiment. FIG. 3 is an enlarged plan view of an area around a fixing hole 17a1 in an inner wiring portion 17a of a connection terminal 17 in FIG. 2. The illustration of the sealing material 21 is omitted in FIG. 3. FIG. 4 is a sectional view taken along a dashed-dotted line Y-Y in FIG. 3, and FIG. 5 is a sectional view taken along a dashed-dotted line X-X in FIG. 3. FIGS. 4 and 5 are each an enlarged sectional view of the area around the fixing hole 17a1 in the inner wiring portion 17a of the connection terminal 17 in FIG. 2.

As described above, the individual connection terminal 17 includes an inner wiring portion 17a and an outer wiring portion 17b. As illustrated in FIGS. 4 and 5, the individual inner wiring portion 17a has a fixing hole 17a1 (a through-hole), a depression 17a2 (a concave portion), a protruding portion 17a3 (a protrusion), a top surface 17a5, a bottom surface 17a6 opposite to the top surface 17a5, and outer side portions 17a7. The top surface 17a5 and the bottom surface 17a6 have a rectangular shape in plan view, and have the same size. In particular, the individual inner wiring portion 17a includes a depression 17a2 and a protruding portion 17a3 on its one end. The outer side portions 17a7 are side surfaces that are opposite to each other in the width direction of the inner wiring portion 17a (±Y directions) and that connect the top surface 17a5 and the bottom surface 17a6.

As illustrated in FIG. 3, the inner wiring portion 17a of the individual connection terminal 17 is embedded in a corresponding one of the placement portions 16d of the frame portion 16 of the case 15. The top surface 17a5 of the individual inner wiring portion 17a is on the same plane with the placement surface 16d1 of the corresponding placement portion 16d. The bottom surface 17a6 and the outer side portions 17a7 of the individual inner wiring portion 17a are in direct contact with the corresponding placement portion 16d (see FIG. 5).

The fixing hole 17a1 is an area that penetrates through the top surface 17a5 and the bottom surface 17a6 of the inner wiring portion 17a. Surfaces (17a4, 17a21, and 17a22) that define the fixing hole 17a1 form one of the side surfaces between the tip surface 17a5 and the bottom surface 17a6. The fixing hole 17a1 may be formed in the center of the inner wiring portion 17a in the ±Y directions in plan view. In addition, the fixing hole 17a1 has a circular shape in plan view, for example. In this case, the fixing hole 17a1 has a cylindrical shape. The diameter of the cylindrical fixing hole 17a1 may be less than the ±Y direction width of the inner wiring portion 17a. The planar shape of the fixing hole 17a1 is not limited to a circular shape. The fixing hole 17a1 may have an oval shape, a rectangular shape, or a polygonal shape in plan view. When the fixing hole 17a1 has any one of these shapes, the fixing hole 17a1 has a corresponding columnar shape. The cylindrical or columnar fixing hole 17a1 is surrounded by an inner wall portion (side surface) 17a4. Overall, the inner wall portion 17a4 may have a smooth surface. The +Z direction end portion of the fixing hole 17a1 is in contact with the depression 17a2.

The depression 17a2 is a portion that is offset from the inner wall portion 17a4 of the fixing hole 17a1 and part of the top surface 17a5. That is, the depression 17a2 is a portion that is deviated (offset) from the inner wall portion 17a4 of the fixing hole 17a1 in a radial direction of the fixing hole 17a1 in plan view. Specifically, the depression 17a2 is a portion in a predetermined region that is offset in the −Z direction from the top surface 17a5 and that is offset in a radial direction of the fixing hole 17a1 from the inner wall portion 17a4 of the fixing hole 17a1. The depth (in the −Z direction) of the depression 17a2 (a wall portion 17a22, which will be described below) may be half of the thickness of the inner wiring portion 17a, for example.

This depression 17a2 is a rectangular area enclosed by a dashed line in the sectional view in FIG. 4. The depression 17a2 includes a bottom portion (flat surface) 17a21 and a wall portion 17a22. The bottom portion 17a21 has a circular ring shape in plan view, and faces the +Z direction opening of the fixing hole 17a1. The width of the bottom portion 17a21 in plan view from the inner wall portion 17a4 to the wall portion 17a22 is the offset distance. Overall, the bottom portion 17a21 may have approximately the same width. The bottom portion 17a21 is approximately parallel to the corresponding placement surface 16d1 and the top surface 17a5 of the inner wiring portion 17a. Overall, the bottom portion 17a21 may have a smooth surface. In other words, in the fixing hole 17a1, a side surface (wall portion 17a22) is formed by offsetting a side surface (inner wall portion 17a4) outward in a radial direction (a direction orthogonal and a flat surface (bottom portion 17a21) is formed by offsetting the top surface 17a5 downward in-Z direction (a direction orthogonal to the top surface 17a5), whereby a step (depression 17a2) is formed by the side surface (wall portion 17a22) and the flat surface (bottom portion 17a21), to form the concave portion 17a2 inside the fixing hole 17a1.

The wall portion 17a22 is integrally connected to the outer edge of the bottom portion 17a21. The connection portion of the wall portion 17a22 and the bottom portion 17a21 may form a right angle or a curved surface. If the connection portion forms a curved surface, a corresponding one of the fixing portions 16f, which will be described below, is easily and tightly inserted into this fixing hole 17al. Overall, the wall portion 17a22 may have approximately the same depth (height).

In plan view, the individual wall portion 17a22 may have a circular shape having its center matching the center of the inner wall portion 17a4 of the corresponding fixing hole 17a1. In plan view, the diameter of the individual wall portion 17a22 is greater than the diameter of the inner wall portion 17a4 of the corresponding fixing hole 17al. In addition, in plan view, the diameter of the individual wall portion 17a22 may be any size, as long as the corresponding fixing portion 16f is able to sufficiently hold and fix the corresponding inner wiring portion 17a. The planar shape of the individual depression 17a2 is not limited to a circular shape. The planar shape of the individual depression 17a2 may be an oval shape, a rectangular shape, or a polygonal shape.

In a sectional view as in FIG. 4, the inner surface of the above-described fixing hole 17a1 may be deemed as a side surface, for example. In this case, the depression 17a2 may be deemed as a portion that is offset from the side surface (inner surface) of the fixing hole 17a1.

The protruding portion 17a3 is formed in a ring-shaped area around the outer edge of the depression 17a2 in plan view. In other words, the protruding portion 17a3 is located in an area between the depression 17a2 and a bonding portion 20a, which will be described below, and is adjacent to the depression 17a2. The protruding portion 17a3 may have a continuous or discontinuous ring shape on the top surface 17a5. This protruding portion 17a3 is a burr generated on the top surface 17a5 when the depression 17a2 is manufactured by processing the connection terminal 17. Thus, the protruding portion 17a3 may be formed asymmetrically in plan view and in side view. The protruding portion 17a3 is formed to protrude around the outer edge of the depression 17a2. The individual protruding portion 17a3 may have a different shape or size.

The protruding portion 17a3 protrudes in the +Z direction from the outer edge of the depression 17a2 to a height above the top surface 17a5 of the inner wiring portion 17a. The height of the protruding portion 17a3 protruding from the top surface 17a5 in the +Z direction is less than the height of the portion of the fixing portion 16f, which will be described below, the portion protruding from the top surface 17a5. Details of the processing method of the depression 17a2 will be described below.

In FIG. 3, a fixing hole 17a1, a depression 17a2, and a fixing portion 16f are formed between ±Y direction end portions of the inner wiring portion 17a. Alternatively, the inner wiring portion 17a may have two or more fixing holes 17a1, depressions 17a2, and fixing portions 16f.

The fixing portions 16f, each of which is part of a corresponding one of the placement portions 16d of the frame portion 16, are formed in the fixing holes 17a1 and the depressions 17a2 formed in their respective inner wiring portions 17a when the connection terminals 17 are integrally molded with the case 15 by insert molding. When the inner wiring portions 17a of the connection terminals 17 are formed with the case 15 by insert molding, the bonding portions 20a, which will be described below, the fixing holes 17al, and the protruding portions 17a3 of the inner wiring portions 17a are disposed in the storage region 16i of the case 15.

The individual fixing portion 16f fills the fixing hole 17a1 and the depression 17a2 of the corresponding inner wiring portion 17a, and protrudes vertically upward from the top surface 17a5 of this inner wiring portion 17a. The fixing portion 16f has a circular shape in plan view as illustrated in FIG. 3. In addition, the fixing portion 16f has a T shape in a sectional view, as illustrated in FIGS. 4 and 5. The fixing portion 16f includes a protruding portion 16g and a pressing portion 16h.

The individual protruding portion 16g is integrally connected to the corresponding placement portion 16d included in the frame portion 16. As illustrated in FIGS. 4 and 5, the protruding portion 16g is a rectangular portion enclosed by a dotted line in the center of the fixing portion 16f. The protruding portion 16g has a cylindrical shape. The lower end (−Z direction) of the protruding portion 16g has a circular shape matching the shape of the fixing hole 17a1 in plan view. The lower end of the protruding portion 16g is on the same plane with the bottom surface 17a6 of the inner wiring portion 17a. The upper end (+Z direction) of the protruding portion 16g has a circular shape in plan view, and is located above the top surface 17a5 of the inner wiring portion 17a. The height of a portion of the protruding portion 16g, the portion protruding from the top surface 17a5 of the inner wiring portion 17a, may be approximately the same as the −Z direction depth of the depression 17a2, for example. In this case, the protruding height of the protruding portion 16g may be half of the thickness of the inner wiring portion 17a. The upper end of the protruding portion 16g is located above the +Z direction height of the protruding portion 17a3. The lower portion of the outer surface of the protruding portion 16g is in contact with the fixing hole 17a1.

The pressing portion 16h is formed to enclose the entire circumference of the protruding portion 16g. The pressing portion 16h is an individual rectangular portion enclosed by a dotted line adjacent to a side portion of the protruding portion 16g in the ±X directions or ±Y directions in sectional views in FIGS. 4 and 5. The pressing portion 16h is a ring portion in plan view formed around the protruding portion 16g of the fixing portion 16f. That is, the pressing portion 16h is a hollow portion having a cylindrical shape. The fixing portion 16f is formed such that the outer surface of the cylindrical protruding portion 16g is in contact with the inner side of the hollow pressing portion 16h.

The upper end (+Z direction) of the pressing portion 16h is on the same plane with the upper end of the protruding portion 16g. The lower end (−Z direction) of the pressing portion 16h is in contact with the bottom portion 17a21 of the depression 17a2. That is, the ±Z direction length of the pressing portion 16h is equal to the length from the bottom portion 17a21 of the depression 17a2 to the upper end of the protruding portion 16g. The upper portion of the pressing portion 16h protrudes from the top surface 17a5 of the inner wiring portion 17a, and the lower portion of the pressing portion 16h is in contact with the wall portion 17a22 of the depression 17a2.

The present embodiment assumes an example in which the upper end of the fixing portion 16f is flat. The upper end of the fixing portion 16f may be formed differently. For example, a group of concave and convex portions may be formed uniformly on the upper end of the fixing portion 16f. Alternatively, spire-like portions may be formed on the upper end of the fixing portion 16f. In this way, as will be described below, when the fixing portion 16f is sealed by the sealing material 21, the adhesion between the fixing portion 16f and the sealing material 21 is improved by these portions described above.

In addition, the individual fixing portion 16f fills the fixing hole 17a1 and the depression 17a2 of the corresponding inner wiring portion 17a. Thus, the planar shape of the fixing portion 16f depends on the planar shape of the depression 17a2. For example, if the planar shape of the depression 17a2 is rectangular, the planar shape of the fixing portion 16f is also rectangular.

In addition, a bonding portion 20a, which is an end portion of a bonding wire 20, is bonded to a wire connection area 17a8 of the top surface 17a5 of the individual inner wiring portion 17a. The bonding portion 20a is bonded to the wire connection area 17a8 located in the ±Y direction center of the top surface 17a5 of the individual inner wiring portion 17a. The bonding portion 20a of the bonding wire 20 is bonded to the top surface 17a5 by a bonding apparatus. To prevent the bonding portion 20a of the bonding wire 20 from being detached from the top surface 17a5 of the individual inner wiring portion 17a, it is desirable that the location of the bonding portion 20a be as close as possible to the fixing portion 16f. Thus, it is desirable that the distance between the bonding portion 20a and the fixing portion 16f in the +X direction be as short as possible. Any distance is applicable, as long as a bonding apparatus is able to perform the bonding between the fixing portion 16f and the bonding portion 20a. In plan view, the distance (±X directions) between a side portion of the fixing portion 16f, the side portion being located in the direction of the bonding portion 20a, and the bonding portion 20a may be, for example, 1.3 mm or less.

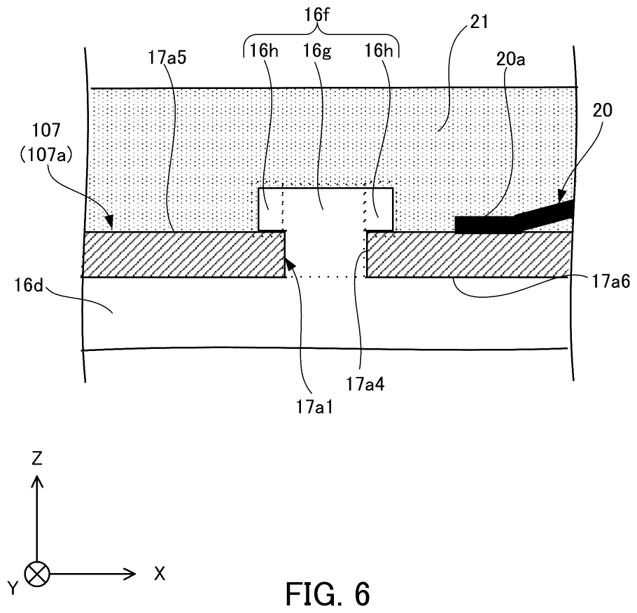

Next, a reference example, which will be compared with the connection terminals 17 according to the first embodiment, will be described with reference to FIG. 6. FIG. 6 is a side sectional view of a connection terminal included in a semiconductor device according to the reference example. FIG. 6 corresponds to the sectional view taken along the dashed-dotted line Y-Y in FIG. 3 according to the first embodiment. FIG. 6 illustrates a reference example compared with the connection terminal 17 in FIG. 4.

As illustrated in FIG. 6, an inner wiring portion 107a of an individual connection terminal 107 according to the reference example differs from the inner wiring portion 17a of the individual connection terminal 17 according to the first embodiment in that the inner wiring portion 107a does not include a depression 17a2 and a protruding portion 17a3. The inner wiring portion 107a of the connection terminal 107 according to the reference example includes the same components as those of the connection terminal 17 according to the first embodiment, except the depression 17a2 and the protruding portion 17a3.

As in the first embodiment, the individual connection terminal 107 according to the reference example is embedded in a placement surface 16d1 of a corresponding placement portion 16d, as illustrated in FIG. 6. A fixing portion 16f is embedded in a fixing hole 17a1 in the inner wiring portion 107a, and protrudes vertically upward from a top surface 17a5 of the inner wiring portion 107a. The fixing portion 16f has a T shape in a sectional view, as illustrated in FIG. 6. The fixing portion 16f includes a protruding portion 16g and a pressing portion 16h.

As in the first embodiment, the protruding portion 16g is integrally connected to the placement portion 16d included in a frame portion 16. As illustrated in FIG. 6, the protruding portion 16g protrudes vertically upward from the top surface 17a5 of the inner wiring portion 107a.

The pressing portion 16h is formed to enclose the entire circumference of the protruding portion 16g. Thus, in plan view, the pressing portion 16h is a ring portion formed around the protruding portion 16g, and in contact with the top surface 17a5 of the inner wiring portion 107a.

Delamination easily occurs in the interface between the frame portion 16 of the case 15 included in the semiconductor device 10 and the sealing material 21. In particular, because the adhesion between the connection terminal 107 and the frame portion 16 is low in the reference example, the delamination could occur between the connection terminal 107 and the frame portion 16. If the delamination that has occurred between the connection terminal 107 and the frame portion 16 extends, delamination occurs between the frame portion 16 and the sealing material 21. In addition, if the delamination that has occurred between the frame portion 16 and the sealing material 21 further extends and reaches a bonding portion 20a, delamination could occur between the connection terminal 107 and a bonding wire 20. As a result, the insulation inside the semiconductor device 10 could not be maintained. In addition, moisture intrudes into the semiconductor device 10 from the outside through the delamination, and internal components are corroded, for example. These deteriorate the characteristics of the semiconductor device 10.

Thus, the above-described semiconductor device 10 includes a bonding wire 20 electrically connected to the semiconductor chip 13a or 13b, a connection terminal 17, a case 15, and sealing material 21 sealing the connection terminal 17 in the case 15. The connection terminal 17 has a top surface 17a5, a bottom surface 17a6, and outer side portions 17a7, and has, on one end of the top surface 17a5, a wire connection area 17a8 to which the bonding wire 20 is connected, a depression 17a2 that is offset from an inner wall portion 17a4 and part of the top surface 17a5, a protruding portion 17a3 that is located in an area between the depression 17a2 and the wire connection area 17a8 and is adjacent to the depression 17a2. The case 15 has a fixing portion 16f that is in contact with the bottom surface 17a6, the inner wall portion 17a4, and the depression 17a2 of the connection terminal 17 and that extends upward along the inner wall portion 17a4 to a height above the top surface 17a5 and the protruding portion 17a3 of the connection terminal 17 via the depression 17a2. The wire connection area 17a8, the depression 17a2, and the protruding portion 17a3 are disposed on the inner side of the case 15.

The bottom portion 17a21 of the individual depression 17a2 is the portion that is the most prone to delamination in the interface between the frame portion 16 and the connection terminal 17. When delamination occurs on the bottom portion 17a21, the delamination extends. However, because of the wall portion 17a22, the path of the extension bends, and consequently, the extension of the delamination is reduced. As a result, the delamination between the frame portion 16 and the connection terminal 17 is reduced.

In addition, because the protruding portion 17a3, which is generated at the manufacture of the depression 17a2, is located on the top surface 17a5 around the depression 17a2, movement of the fixing portion 16f is reduced by the protruding portion 17a3, and therefore, movement of the fixing portion 16f is reduced. In addition, misalignment of the connection terminal 17 with respect to the frame portion 16 is prevented. Furthermore, because the protruding portion 17a3 engages with the sealing material 21, the adhesion between the frame portion 16 and the sealing material 21 is improved. In addition, because the protruding portion 17a3 is present on the delamination extension path, the extension of the delamination is reduced, and consequently, the delamination between the frame portion 16 and the sealing material 21 is also reduced.

If a bonding wire 20 is bonded to an inner wiring portion 17a in a state in which the adhesion between the corresponding connection terminal 17 and the frame portion 16 is low, the inner wiring portion 17a is vibrated by the vibration generated at the time of the bonding. This vibration generated when the bonding wire 20 is boned to the inner wiring portion 17a causes friction heat, and the bonding between the top surface 17a5 and the bonding wire 20 consequently becomes unstable. In the present embodiment, since the adhesion between the connection terminal 17 and the frame portion 16 is improved, it is possible to stably bond the bonding wire 20 to the connection terminal 17 while preventing misalignment of the connection terminal 17. The bonding performance between the connection terminal 17 and the bonding wire 20 is improved. In addition, it is possible to significantly expand the range of options for the material, diameter, etc., of the bonding wire 20.

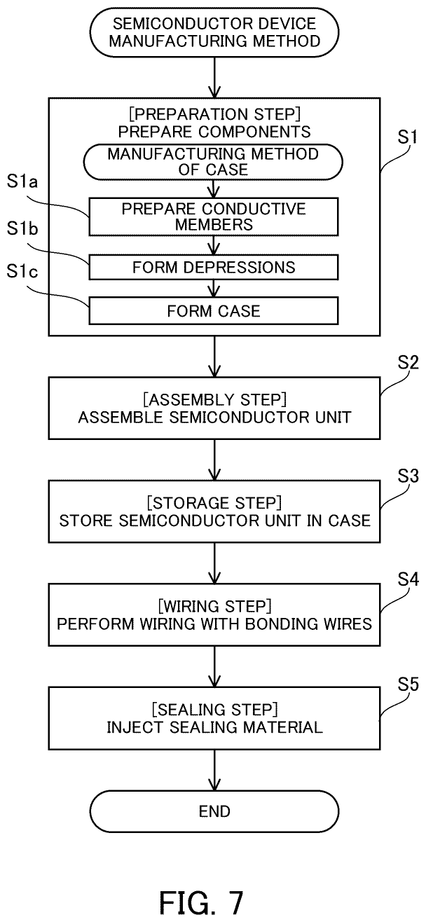

Next, a method for manufacturing the semiconductor device 10 will be described with reference to FIG. 7. FIG. 7 is a flowchart illustrating a method for manufacturing the semiconductor device according to the first embodiment. First, a preparation step of preparing the components of the semiconductor device 10 is performed (step S1 in FIG. 7). In step S1, the components of the semiconductor device 10 are prepared. These components are, for example, the insulated circuit board 12, the semiconductor chips 13a and 13b, the case 15, the heat dissipation plate 14, and the sealing material 21. In addition to these components, parts and manufacturing apparatuses needed to manufacture the semiconductor device 10 are also prepared.

The manufacturing method of the case 15 prepared in the preparation step is as follows. First, conductive members (without the fixing holes 17a1) are prepared (step S1a in FIG. 7). A plurality of long thin conductive members having a flat plate shape are acquired from a conductive plate. These conductive members are joined together by a tie bar. The conductive members include the inner wiring portions 17a and outer wiring portions 17b of the connection terminals 17 as linear portions. Holes used as the fixing holes 17a1 are each formed in a predetermined location of the individual inner wiring portion 17a included in the plurality of conductive members.

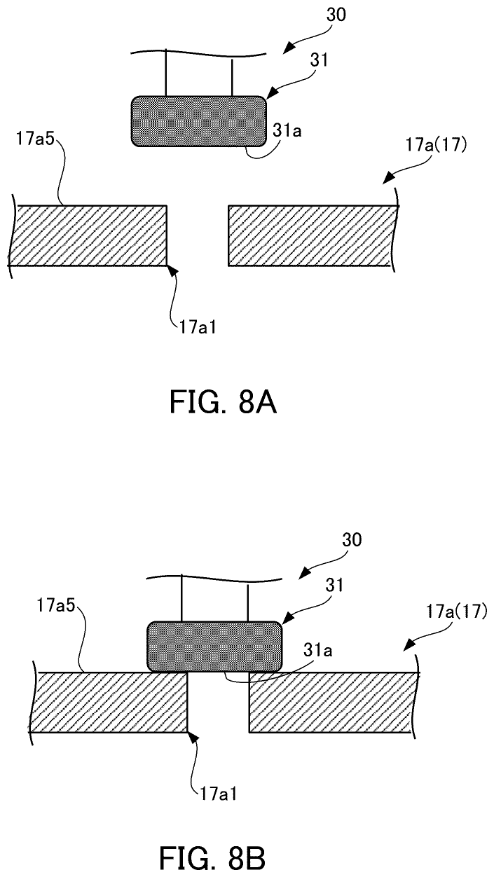

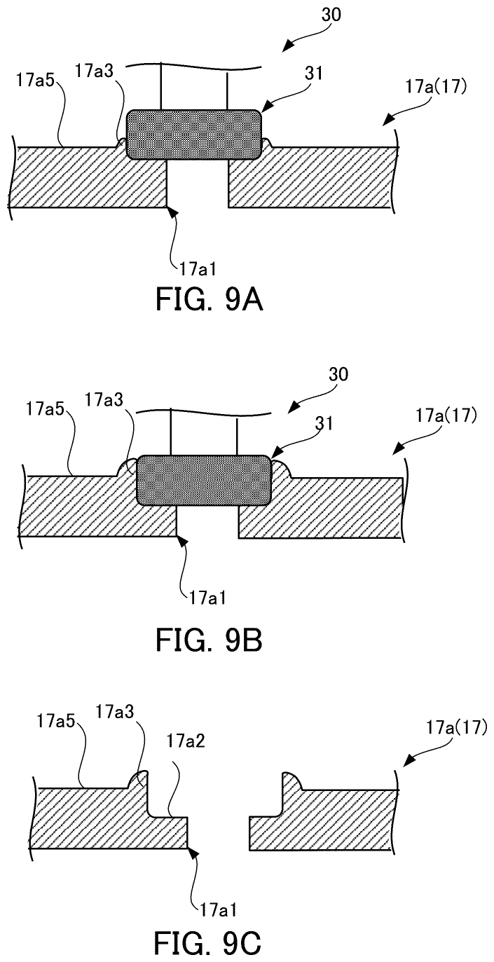

Next, depressions are formed in the plurality of conductive members prepared in step S1a (step S1b in FIG. 7). Forming a concave portion in the individual inner wiring portion 17a included in the plurality of conductive members will be described with reference to FIGS. 8A and 8B and FIGS. 9A to 9C. FIGS. 8A and 8B are each a first side sectional view illustrating a work process performed on a conductive member according to the first embodiment. FIGS. 9A to 9B are each a second side sectional view illustrating the work process performed on the conductive member according to the first embodiment. FIGS. 8A and 8B and FIGS. 9A to 9C are side views of the work process performed on an inner wiring portion 17a included in a conductive member. In FIGS. 8A and 8B and FIGS. 9A to 9C, the work process is illustrated in chronological order.

First, an inner wiring portion 17a of the plurality of conductive members is set on a predetermined placement surface of a press apparatus. In this state, the bottom surface 17a6 of the inner wiring portion 17a is disposed on the placement surface, and the fixing hole 17a1 faces vertically upward. Next, a press jig 30 is positioned immediately above the fixing hole 17a1. The press jig 30 includes a press portion 31 including a flat press surface 31a. The press portion 31 may have, for example, a cylindrical shape, and in plan view, the press surface 31a may have a circular shape. The press surface 31a has a diameter greater than that of the fixing hole 17a1. In addition, the lower end corners of the press portion 31 may be rounded or chamfered. As illustrated in FIG. 8A, the press portion 31 is positioned such that the press surface 31a faces the fixing hole 17a1. Next, the press portion 31 is lowered toward the fixing hole 17a1 and is brought into contact with the top surface 17a5 of the inner wiring portion 17a of the conductive members (FIG. 8B).

Next, the press portion 31 in contact with the top surface 17a5 of the inner wiring portion 17a of the plurality of conductive members is lowered further, and the protruding portion 17a3, which is a burr around the press portion 31, is consequently formed (FIGS. 9A and 9B). When the press portion 31 is lowered by a predetermined distance, the lowering is stopped, and the press portion 31 is removed. In this way, the depression 17a2 is formed around the fixing hole 17a1 in the top surface 17a5 of the inner wiring portion 17a of the conductive members (FIG. 9C). The protruding portion 17a3 is also formed around the depression 17a2 of the inner wiring portion 17a.

Next, the case 15 including the connection terminals 17 is formed (step S1c in FIG. 7). The plurality of conductive members having the depressions formed in step S1b are set in a predetermined mold. Case material is first injected into this mold, and is next hardened. Next, the mold is removed. In this state, each of the plurality of conductive members extends straight to the outside from a side portion of the frame portion 16 of the case 15. Next, the tie bar is removed, and the conductive members extending to the outside of the frame portion 16 are bend in the +Z direction outside the frame portion 16. Thus, the case 15 including the connection terminals 17 including the inner wiring portions 17a and the outer wiring portions 17b is obtained. It is easy to mold the case 15 whose connection terminals 17 have been bent outside of the frame portion 16.

Next, an assembly step of assembling the semiconductor unit 11 is performed (step S2 in FIG. 7). The semiconductor chips 13a and 13b are bonded to predetermined circuit patterns 12b of the insulated circuit board 12 via the bonding material 13a1 and 13b1.

Next, a storage step of storing the semiconductor unit 11 in the case 15 is performed (step S3 in FIG. 7). The semiconductor unit 11 is bonded to the front surface of the heat dissipation plate 14 via bonding material 11a. The main component of the bonding material 11a may be the same as that of the bonding material 13a1 and 13b1. The case 15 is attached to the outer periphery portion of the heat dissipation plate 14 via the adhesive 14a. The adhesive 14a is heated for a predetermined time at a predetermined temperature and is hardened, and the case 15 is consequently bonded to the heat dissipation plate 14.

Next, a wiring step of performing wiring with bonding wires is performed (step S4 in FIG. 7). In this step, bonding for suitably connecting the inner wiring portions 17a of the connection terminals 17, the semiconductor chips 13a and 13b, and the circuit patterns 12b of the insulated circuit board 12 with the bonding wires 20 is performed.

Next, a sealing step of filling the storage region 16i of the case 15 with the sealing material 21 is performed (step S5 in FIG. 7). The sealing material 21 is injected into the storage region 16i of the frame portion 16 until the bonding wires 20 are completely sealed. As a result, the semiconductor device 10 is obtained.

### Modifications of First Embodiment

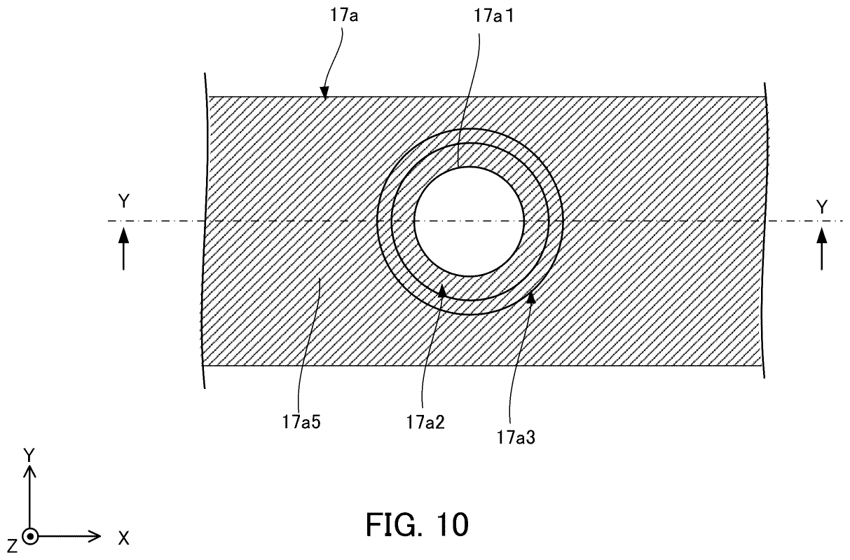

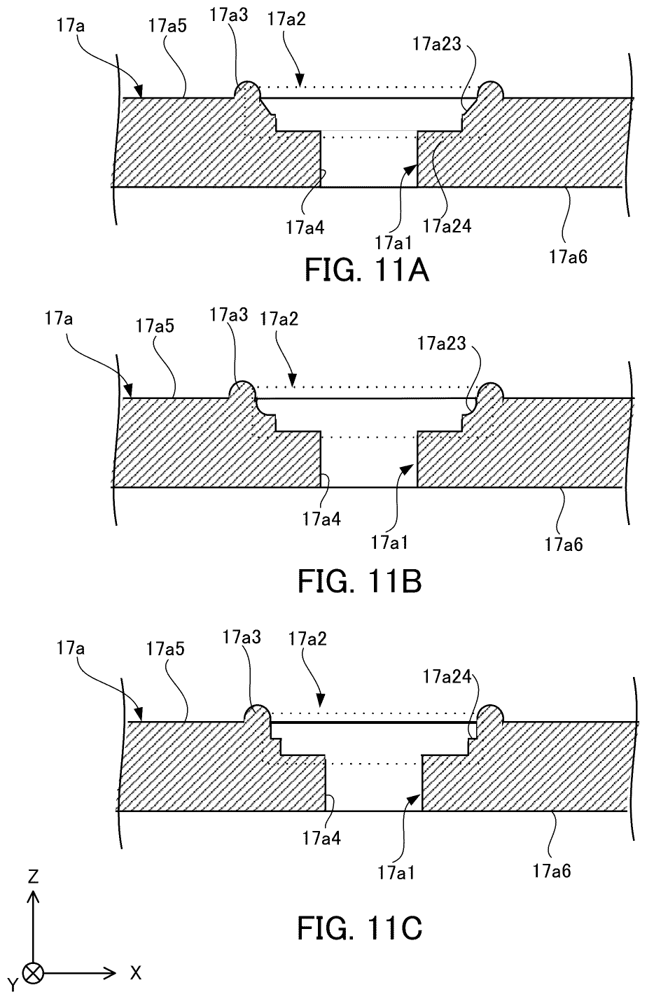

Connection terminals 17 according to modifications of the first embodiment will be described with reference to FIG. 10 and FIGS. 11A to 11C. FIG. 10 is a plan view of a connection terminal according to the first embodiment (modifications). FIGS. 11A to 11C are each a side sectional view of a connection terminal according to the first embodiment (modifications). FIGS. 11A to 11C are each a sectional view taken along a dashed-dotted line Y-Y in FIG. 10. FIG. 10 and FIGS. 11A to 11C each illustrate only an inner wiring portion 17a of a connection terminal 17, and the illustration of other components is omitted.

Depressions 17a2 of the inner wiring portions 17a included in the connection terminals 17 according to the modifications are processed differently from the depressions 17a2 of the inner wiring portions 17a of the connection terminals 17 according to the first embodiment illustrated in FIGS. 3 to 5. Other aspects of the inner wiring portions 17a of the connection terminals 17 according to the modifications are the same as those of the inner wiring portions 17a according to the first embodiment.

The inner wiring portion 17a included in each of the connection terminals 17 according to the modifications also includes a fixing hole 17a1, a depression 17a2, and a protruding portion 17a3. The fixing hole 17a1 is the same as that illustrated in FIGS. 3 to 5. The protruding portion 17a3 is also formed around the depression 17a2, as illustrated in FIGS. 3 to 5.

As is the case with FIGS. 3 to 5, the individual depression 17a2 according to the modifications is a portion that is offset to the outside from the inner wall portion 17a4 of the fixing hole 17a1 in plan view. This depression 17a2 is a rectangular area enclosed by a dotted line in a sectional view in each of FIGS. 11A to 11C.

The depression 17a2 illustrated in FIG. 11A has an opening portion 17a23, which has been chamfered in a continuous ring around the periphery of the depression 17a2. The depression 17a2 illustrated in FIG. 11A has been chamfered such that the +Z direction side of the opening portion 17a23 is wider than the −Z direction side of the opening portion 17a23.

The depression 17a2 illustrated in FIG. 11B has an opening portion 17a23, which has been rounded in a continuous ring around the periphery of the depression 17a2. The opening portion 17a23 is dented toward the inner wiring portion 17a from the depression 17a2.

In addition, the depression 17a2 illustrated in FIG. 11C has a step 17a24, which has been formed in a continuous ring along the wall portion 17a22 of the depression 17a2. The step 17a24 may be approximately parallel to the bottom portion 17a21 of the depression 17a2.

A fixing portion 16f is also formed in each of the fixing holes 17a1 and the depressions 17a2 illustrated in FIGS. 11A to 11C. In FIGS. 11A to 11C, because the contact area between the fixing portion 16f and the rounded or chamfered opening portion 17a23 and the contact area between the fixing portion 16f and the step 17a24 are increased, the adhesion is increased. Thus, the individual inner wiring portion 17a is fixed by the corresponding f01112fixing portion 16f more reliably.

To form any one of the above-described depressions 17a2, first, the press portion 31 of the press jig 30 illustrated in FIGS. 8A and 8B and FIGS. 9A to 9C is shaped to match the shape of the corresponding depression 17a2. By performing press work on a fixing hole 17a1 in an inner wiring portion 17a by using this press jig 30, the inner wiring portion 17a having any one of the depressions 17a2 illustrated in FIGS. 11A to 11C is obtained.

### Second Embodiment

Unlike the first embodiment, an inner wiring portion 17a of an individual connection terminal 17 according to a second embodiment does not include a fixing hole 17a1. In the second embodiment, depressions 17a2 are formed on side portions of the individual inner wiring portion 17a. Other components included in a semiconductor device 10 according to the second embodiment are the same as those of the semiconductor device 10 according to the first embodiment.

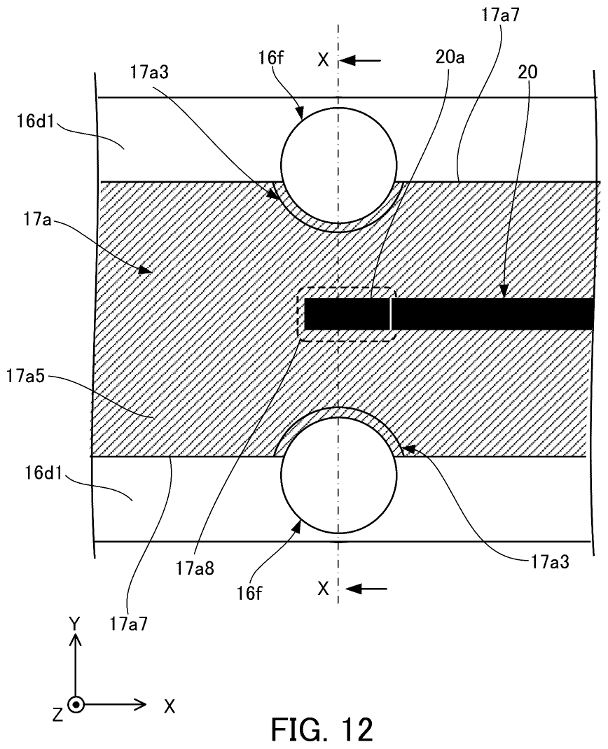

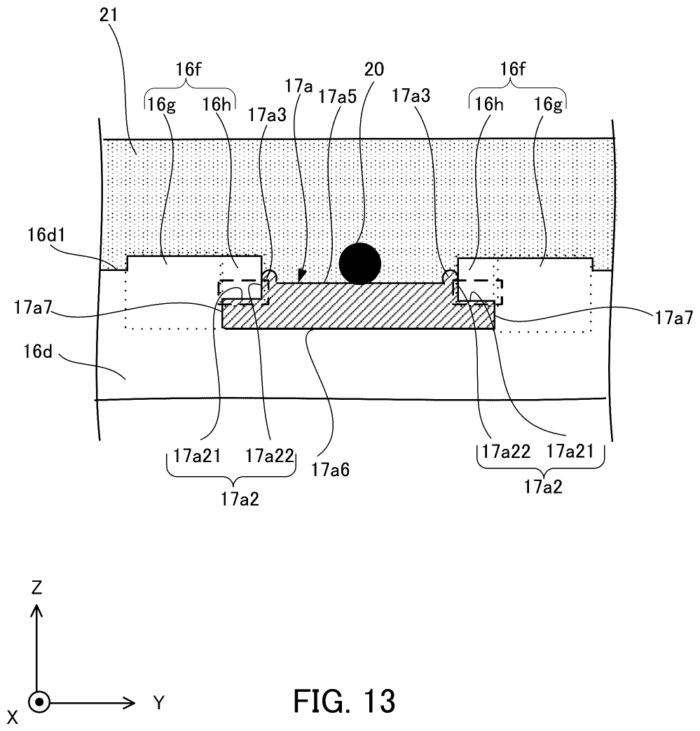

A connection terminal 17 according to the second embodiment will be described with reference to FIGS. 12 and 13. FIG. 12 is a plan view of a main portion of a connection terminal included in the semiconductor device according to the second embodiment. FIG. 13 is a side sectional view of the main portion of the connection terminal included in the semiconductor device according to the second embodiment. The illustration of sealing material 21 is omitted in FIG. 12. FIG. 13 is a sectional view taken along a dashed-dotted line X-X in FIG. 12.

As described above, the individual connection terminal 17 includes an inner wiring portion 17a and an outer wiring portion 17b. As illustrated in FIGS. 12 and 13, the individual inner wiring portion 17a includes depressions 17a2, protruding portions 17a3, a top surface 17a5, a bottom surface 17a6, and outer side portions 17a7. The top surface 17a5 and the bottom surface 17a6 each have a rectangular shape in plan view, and each have the same size. The outer side portions 17a7 connect both ends of the top surface 17a5 and the bottom surface 17a6, are parallel to each other, and extend in the +X directions.

As illustrated in FIG. 13, the inner wiring portion 17a of the individual connection terminal 17 is embedded in a corresponding one of the placement portions 16d of the frame portion 16 of the case 15. The top surface 17a5 of the individual inner wiring portion 17a is on the same plane with the placement surface 16d1 of the corresponding placement portion 16d. In addition, the bottom surface 17a6 and the pair of outer side portions 17a7 of the inner wiring portion 17a are in direct contact with the placement portion 16d (see FIGS. 12 and 13).

The individual depression 17a2 is a portion that is offset from a corresponding one of the outer side portions 17a7 and part of the top surface 17a5 of the connection terminal 17. That is, the individual depression 17a2 is a portion that is deviated (offset) from a corresponding one of the outer side portions 17a7 of the connection terminal 17 to the inner side in plan view. Specifically, the individual depression 17a2 is a portion in a predetermined region that is offset in the −Z direction from the top surface 17a5 of the connection terminal 17 and that is offset from the corresponding outer side portion 17a7 to the inner side (to the corresponding one of the ±Y directions).

The individual depression 17a2 is a rectangular area enclosed by a dashed line in the sectional view in FIG. 13. The individual depression 17a2 is formed on each of the outer side portions 17a7 located on two ends of the inner wiring portion 17a. The individual depression 17a2 includes a bottom portion 17a21 and a wall portion 17a22.

The outer edge of the individual bottom portion 17a21 has an arc-like shape in plan view. In plan view of the bottom portion 17a21, the width from the corresponding outer side portion 17a7 to the corresponding wall portion 17a22 is the offset distance. The offset distance may be any distance, as long as the corresponding fixing portion 16f is able to sufficiently hold and fix the inner wiring portion 17a. The offset distance is, for example, 0.25 mm. The bottom portion 17a21 is approximately parallel to the placement surface 16d1 and the top surface 17a5 of the inner wiring portion 17a. Overall, the bottom portion 17a21 may have a smooth surface. The bottom portion 17a21 may be deemed as part of a circular shape or an oval shape in plan view. Alternatively, the bottom portion 17a21 may have a rectangular shape or a polygonal shape. The depressions 17a2 may be part of a circular shape or an oval shape in plan view. The depression 17a2 may have a rectangular shape or a polygonal shape.

In addition, regarding each of the outer side portions 17a7 on which the depressions 17a2 are formed, a cutout may be formed from the bottom portion 17a21 of the depression 17a2 to the bottom surface 17a6 of the inner wiring portion 17a. The cutout has, for example, an arc-like shape in plan view. The widths of the individual cutout in the ±X directions and ±Y directions are less than those of the depression 17a2 in these directions.

The individual wall portion 17a22 is integrally connected to the outer edge of the corresponding bottom portion 17a21. The connection portion of the wall portion 17a22 and the bottom portion 17a21 may form a right angle or a curved surface. If this connection portion forms a curved surface, a corresponding one of the fixing portions 16f, which will be described below, is easily and tightly inserted into the depression 17a2. Overall, the individual wall portion 17a22 may have approximately the same depth (height).

In plan view, as is the case with the bottom portion 17a21, the wall portion 17a22 forms part of a circular shape or part of an arc-like shape or has a rectangular shape or a polygonal shape. In side view, the individual wall portion 17a22 is integrally connected to the outer edge of the corresponding bottom portion 17a21.

The individual protruding portion 17a3 is formed in an area along the outer edge of the corresponding depression 17a2 in plan view. In other words, the individual protruding portion 17a3 is located in an area between the corresponding depression 17a2 and a bonding portion 20a, which will be described below, and is adjacent to this depression 17a2. The protruding portion 17a3 may be formed continuously or discontinuously along the entire outer edge of the depression 17a2 on the top surface 17a5. The individual protruding portion 17a3 is a burr generated on the top surface 17a5 when the corresponding depression 17a2 is manufactured by processing the corresponding connection terminal 17. Thus, the individual protruding portion 17a3 may be formed asymmetrically in plan view and in side view. The individual protruding portion 17a3 is formed to protrude around the outer edge of the corresponding depression 17a2. The individual protruding portion 17a3 may have a different shape or size. The individual protruding portion 17a3 protrudes in the +Z direction from the outer edge of the corresponding depression 17a2 to a height above the top surface 17a5 of the corresponding inner wiring portion 17a. The +Z direction height of a portion of the protruding portion 17a3, the portion protruding from the top surface 17a5, is less than the height of a portion of the fixing portion 16f, which will be described below, the portion protruding from the top surface 17a5.

In FIG. 13, one depression 17a2 and one fixing portion 16f are formed on the +Y direction outer side portion 17a7 of the individual inner wiring portion 17a, and one depression 17a2 and one fixing portion 16f are formed on the −Y direction outer side portion 17a7 of the individual inner wiring portion 17a. That is, two depressions 17a2 and two fixing portions 16f are formed on the individual inner wiring portion 17a. The construction of the individual inner wiring portion 17a is not limited to this example. In addition to the two depressions 17a2 and the two fixing portions 16f described above, more depressions 17a2 and more fixing portions 16f may be formed on the individual inner wiring portion 17a. These additional depressions 17a2 and fixing portions 16f may be formed in the LY direction center portions of the inner wiring portion 17a, as in the first embodiment. Alternatively, these additional depressions 17a2 and fixing portions 16f may be formed on the outer side portions 17a7.

In addition, herein, one pair of depression 17a2 and fixing portion 16f are formed to face the other pair of depression 17a2 and fixing portion 16f in the ±Y directions on the outer side portions 17a7 of the inner wiring portion 17a (see FIG. 12). Alternatively, the ±X direction locations of one pair of depression 17a2 and fixing portion 16f may be deviated from the ±X direction locations of the other pair of depression 17a2 and fixing portion 16f. When the connection terminals 17 are integrally molded with the case 15 by insert molding, each fixing portion 16f, which is part of a placement portion 16d of the frame portion 16, is formed in a depression 17a2 formed in a corresponding one of the inner wiring portions 17a.

The individual fixing portion 16f fills a depression 17a2 of the corresponding inner wiring portion 17a, and protrudes vertically upward from the top surface 17a5 of the inner wiring portion 17a. The individual fixing portion 16f may have a circular shape in plan view, as illustrated in FIG. 12. The individual fixing portion 16f may have an oval shape, a rectangular shape, or a polygonal shape in plan view. In addition, as illustrated in FIG. 13, the individual fixing portion 16f is formed in an L shape area indicated by dotted lines in a sectional view and is constituted by a rectangular protruding portion 16g and a rectangular pressing portion 16h in a sectional view. The individual fixing portion 16f includes the protruding portion 16g and the pressing portion 16h.

The individual protruding portion 16g is integrally connected to the corresponding placement portion 16d included in the frame portion 16. As illustrated in FIG. 13, the individual protruding portion 16g is a rectangular portion of the fixing portion 16f, the portion being away from the inner wiring portion 17a and being enclosed by a dotted line. The individual protruding portion 16g forms part of a cylindrical shape. The lower end (−Z direction) of the individual protruding portion 16g is part of a circular shape in plan view, and is on the same plane with the bottom surface 17a6 of the corresponding inner wiring portion 17a. The individual protruding portion 16g may be part of an oval shape in plan view. Alternatively, the individual protruding portion 16g may have a rectangular shape or a polygonal shape in plan view. The upper end (+Z direction) of the individual protruding portion 16g is part of a circular shape in plan view, and is located above the top surface 17a5 of the corresponding inner wiring portion 17a. The height of a portion of the individual protruding portion 16g, the portion protruding from the top surface 17a5 of the corresponding inner wiring portion 17a, may be approximately the same as the −Z direction depth of the corresponding depression 17a2. The upper end of the individual protruding portion 16g is located above the +Z direction height of the corresponding protruding portion 17a3. The upper end of the individual protruding portion 16g may be on the same plane with the corresponding placement surface 16d1.

The individual pressing portion 16h is integrally formed with the corresponding protruding portion 16g in an area of the fixing portion 16f, the area where the protruding portion 16g is not formed. In a sectional view in FIG. 13, the individual pressing portion 16h is a rectangular portion enclosed by a dotted line adjacent to a side portion of the corresponding protruding portion 16g in the +Y direction or −Y direction (in the direction of the corresponding inner wiring portion 17a). In plan view, the pressing portion 16h of the individual circular fixing portion 16f is part of a circle in contact with the corresponding depression 17a2. In plan view, the individual pressing portion 16h may be part of an oval shape. Alternatively, the pressing portion 16h may have a rectangular shape or a polygonal shape in plan view. The individual pressing portion 16h is part of a cylindrical shape, and extends from the bottom portion 17a21 of the corresponding depression 17a2 to the upper end of the corresponding protruding portion 16g.

The (+Z direction) upper end of the individual pressing portion 16h is on the same plane as the upper end of the corresponding protruding portion 16g. In addition, the (−Z direction) lower end of the individual pressing portion 16h is in contact with the bottom portion 17a21 of the corresponding depression 17a2. That is, the ±Z direction length of the individual pressing portion 16h is equal to the length from the bottom portion 17a21 of the corresponding depression 17a2 to the upper end of the corresponding protruding portion 16g. The upper portion of the individual pressing portion 16h protrudes from the top surface 17a5 of the corresponding inner wiring portion 17a, and the lower portion of the individual pressing portion 16h is in contact with the wall portion 17a22 of the corresponding depression 17a2.

The present embodiment assumes an example in which the upper end of the individual fixing portion 16f has a flat surface. The upper end of the individual fixing portion 16f may be formed differently. For example, a group of concave and convex portions may be formed uniformly on the upper end of the individual fixing portion 16f. Alternatively, spire-like portions may be formed on the upper end of the individual fixing portion 16f. In this way, as will be described below, when the fixing portions 16f are sealed by the sealing material 21, the anchor effect is achieved by these portions described above.

In addition, the individual fixing portion 16f fills a depression 17a2 of the corresponding inner wiring portion 17a. Thus, the planar shape of the individual fixing portion 16f depends on the planar shape of the corresponding depression 17a2. For example, if the planar shape of the individual depression 17a2 is rectangular, the planar shape of the corresponding fixing portion 16f is also rectangular.

In addition, a bonding portion 20a, which is an end portion of a bonding wire 20, is bonded to a wire connection area 17a8 of the top surface 17a5 of the individual inner wiring portion 17a. Specifically, a bonding portion 20a is bonded to a wire connection area 17a8 located in the ±Y direction center of the top surface 17a5 of the individual inner wiring portion 17a. The bonding portion 20a of the bonding wire 20 is bonded to the top surface 17a5 by a bonding apparatus. To prevent the bonding portion 20a of the bonding wire 20 from being delaminated from the top surface 17a5 of the inner wiring portion 17a, it is desirable that the individual bonding portion 20a be located near the corresponding fixing portion 16f. As illustrated in FIG. 12, it is desirable that each bonding portion 20a be formed between two fixing portions 16f facing each other. The distance between the individual: fixing portion 16f and the bonding portion 20a is not particularly limited, as long as a bonding apparatus is able to perform the bonding. In plan view, the distance (±Y directions) between a side portion of the individual fixing portion 16f, the side portion being located in the direction of the bonding portion 20a, and the bonding portion 20a may be in a range between 0.45 mm and 0.55 mm. For example, the distance is 0.5 mm.

The semiconductor device 10 according to the second embodiment includes a bonding wire 20, a connection terminal 17, a case 15, and sealing material 21 sealing the connection terminal 17 in the case 15. The connection terminal 17 has a bottom surface 17a6, outer side portions 17a7, depressions 17a2, each of which is offset from a corresponding one of the outer side portions 17a7, a top surface 17a5 to which the bonding wire 20 is connected, and protruding portions 17a3, each of which is located in an area between a corresponding one of the depressions 17a2 and the bonding wire 20 and is adjacent to this corresponding depression 17a2. The portion where the bonding wire 20 is connected to the connection terminal 17, the depressions 17a2, and the protruding portions 17a3 are disposed on the inner side of the case 15. The case 15 has fixing portions 16f, each of which is in contact with the bottom surface 17a6 of the connection terminal 17 and extends to a height above the top surface 17a5 and the corresponding protruding portion 17a3 along the corresponding depression 17a2.

By constructing the semiconductor device 10 as described above, the same advantageous effects according to the first embodiment are obtained. That is, even when delamination occurs at a bottom portion 17a21 and extends, the extension path of the delamination is bent by the corresponding wall portion 17a22. Consequently, the extension of the delamination is reduced. As a result, the delamination between the frame portion 16 and the connection terminal 17 is reduced.

In addition, because the protruding portions 17a3 formed when the depressions 17a2 are manufactured are present on the top surface 17a5 around the depressions 17a2, movement of the fixing portions 16f is reduced by the protruding portions 17a3. Furthermore, misalignment of the connection terminal 17 with respect to the frame portion 16 is prevented. In addition, because the protruding portions 17a3 engage with the sealing material 21, the adhesion between the frame portion 16 and the sealing material 21 is improved. In addition, because the individual protruding portion 17a3 is present on a delamination extension path, the extension of the delamination is reduced, and the delamination between the frame portion 16 and the sealing material 21 is also reduced.

In addition, since the adhesion between the connection terminal 17 and the frame portion 16 is improved, it is possible to stably bond the bonding wire 20 to the connection terminal 17 while preventing misalignment of the connection terminal 17. The bonding performance between the connection terminal 17 and the bonding wire 20 is improved. In addition, it is possible to significantly expand the range of options for the material, diameter, etc., of the bonding wire 20.

### Third Embodiment

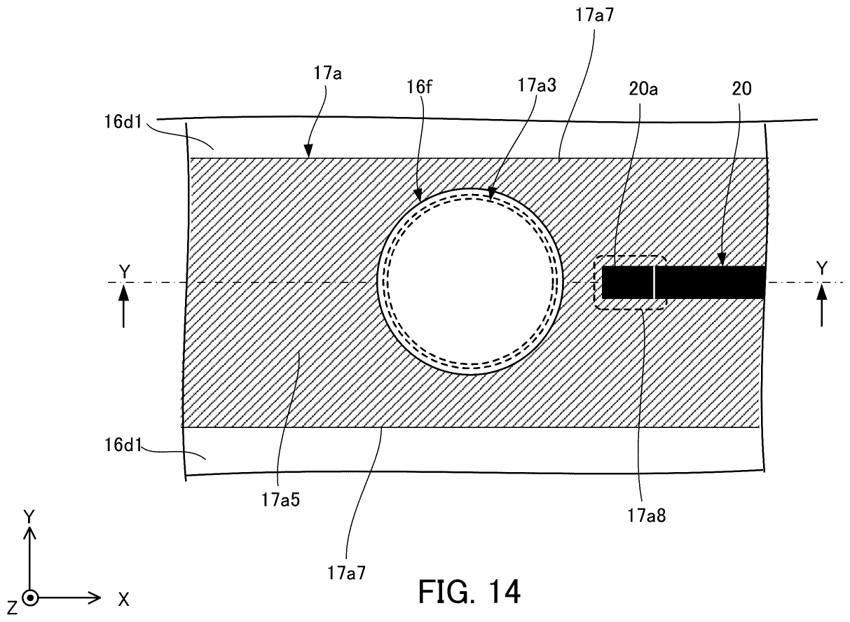

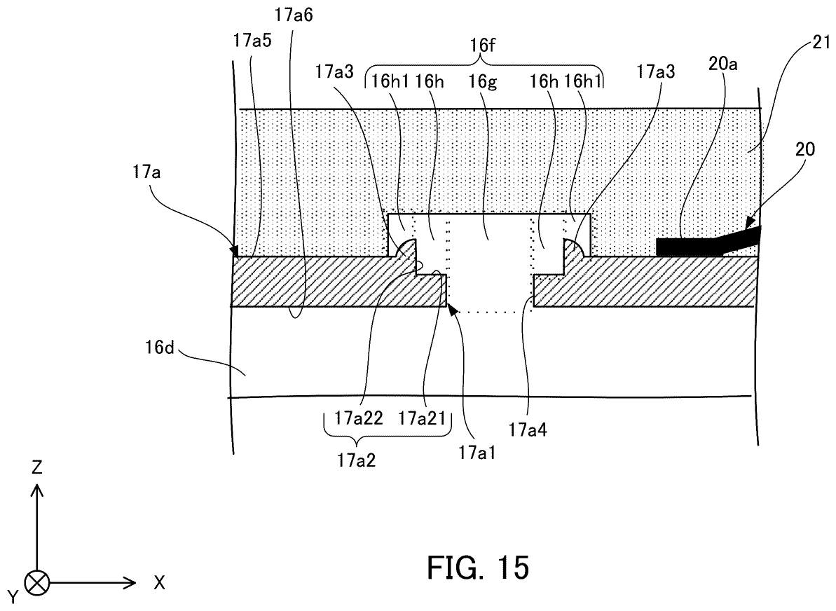

In a third embodiment, an individual fixing portion 16f covers a protruding portion 17a3 of a corresponding connection terminal 17 (a corresponding inner wiring portion 17a), unlike the first embodiment. Components other than these are the same as those of the semiconductor device 10 according to the first embodiment. A fixing portion 16f and a connection terminal 17 according to the third embodiment will be described with reference to FIGS. 14 and 15. FIG. 14 is a plan view of a main portion of a connection terminal included in a semiconductor device according to the third embodiment. FIG. 15 is a side sectional view of the main portion of the connection terminal included in the semiconductor device according to the third embodiment. The illustration of the sealing material 21 is omitted in FIG. 14. The location of the protruding portion 17a3 of the fixing portion 16f is indicated by a dashed line in FIG. 14. FIG. 15 is a sectional view taken along a dashed-dotted line Y-Y in FIG. 14.

As in the first embodiment, the individual connection terminal 17 according to the third embodiment is embedded in the corresponding placement portion 16d of the frame portion 16. The individual connection terminal 17 according to the third embodiment has the same construction as that according to the first embodiment. As in the first embodiment, the individual fixing portion 16f according to the third embodiment fills a fixing hole 17a1 and a depression 17a2 of the corresponding connection terminal 17. In addition, the individual fixing portion 16f seals the corresponding protruding portion 17a3 formed around the outer edge of the depression 17a2 of the corresponding connection terminal 17 (the corresponding inner wiring portion 17a).

The individual fixing portion 16f as described above includes a protruding portion 16g, a pressing portion 16h, and a sealing portion 16h1. As in the first embodiment, the protruding portion 16g and the pressing portion 16h are formed in the fixing hole 17a1 and the depression 17a2 of the corresponding connection terminal 17 (the corresponding inner wiring portion 17a).

The sealing portion 16h1 surrounds the entire circumference of the pressing portion 16h. In a sectional view in FIG. 15, the sealing portion 16h1 is a portion enclosed by a dotted line adjacent to the outer side of the corresponding pressing portion 16h, and completely seals the protruding portion 17a3 of the corresponding connection terminal 17. The sealing portion 16h1 may seal the protruding portion 17a3 and may be in contact with the top surface 17a5 around the protruding portion 17a3. The sealing portion 16h1 of the fixing portion 16f may be formed around the pressing portion 16h and may have a ring shape in plan view. In addition, the outer surface of the sealing portion 16h1 may be sloped, as long as the entire protruding portion 17a3 is sealed. In this case, the fixing portion 16f has a trapezoid shape in which the upper end is the upper base in side view.

Alternatively, the upper end of the protruding portion 16g, the upper end of the pressing portion 16h, and the upper end of the sealing portion 16h1 of the fixing portion 16f may be on the same plane. In addition, for example, a group of concave and convex portions may be formed uniformly on the upper end of the fixing portion 16f. Alternatively, spire-like portions may be formed on the upper end of the fixing portion 16f. In addition, as long as the entire protruding portion 17a3 is sealed, the fixing portion 16f may have a dome-like shape in side view. In this case, the outer surface of the sealing portion 16h1 is a curved surface. When the fixing portion 16f is sealed by the sealing material 21, the area where the fixing portion 16f and the sealing material 21 are firmly attached to each other increases, and the adhesion is consequently improved.

This semiconductor device 10 including the fixing portions 16f provides the same advantageous effects as those according to the first embodiment. In addition, because the fixing portions 16f seal the protruding portions 17a3, movement and misalignment of the connection terminals 17 (the inner wiring portions 17a) are reduced. Compared with the first embodiment, the movement of the connection terminals 17 (the inner wiring portions 17a) is further reduced. In addition, the adhesion of the sealing material 21 to the fixing portions 16f is greater than the adhesion to the connection terminals 17 (the inner wiring portions 17a). Thus, movement and misalignment of the connection terminals 17 (the inner wiring portions 17a) are further reduced.

### Fourth Embodiment

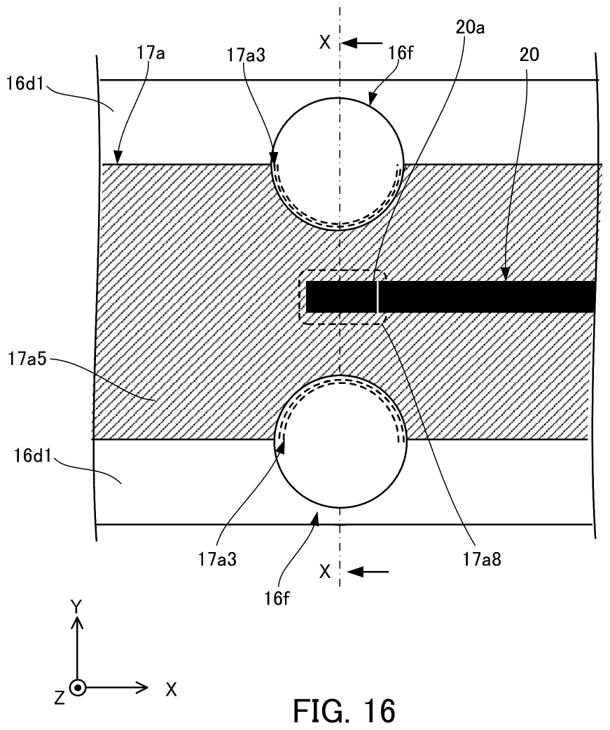

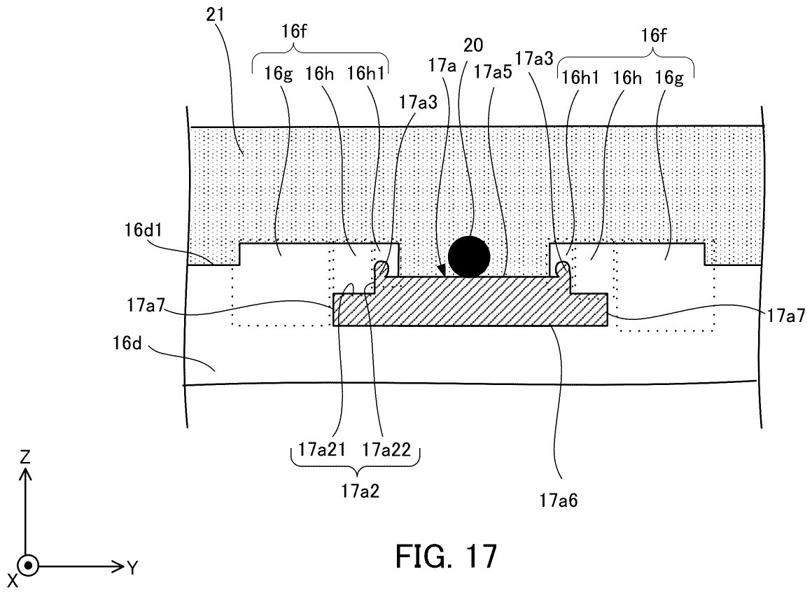

A fourth embodiment differs from the second embodiment in that an individual fixing portion 16f covers a protruding portion 17a3 of a corresponding connection terminal 17 (a corresponding inner wiring portion 17a). Components other than these are the same as those of the semiconductor device 10 according to the second embodiment. Fixing portions 16f and a connection terminal 17 according to the fourth embodiment will be described with reference to FIGS. 16 and 17. FIG. 16 is a plan view of a main portion of a connection terminal included in a semiconductor device according to the fourth embodiment. FIG. 17 is a side sectional view of the main portion of the connection terminal included in the semiconductor device according to the fourth embodiment. The illustration of the sealing material 21 is omitted in FIG. 16. In FIG. 16, the location of an individual protruding portion 17a3 in a corresponding fixing portion 16f is indicated by a dashed line. FIG. 17 is a sectional view taken along a dashed-dotted line Y-Y in FIG. 16.

As in the second embodiment, the individual connection terminal 17 according to the fourth embodiment is embedded in the corresponding placement portion 16d of the frame portion 16. The individual connection terminal 17 according to the fourth embodiment has the same construction as that according to the second embodiment. As in the second embodiment, the individual fixing portion 16f according to the fourth embodiment fills a corresponding fixing hole 17a1 and depression 17a2 formed on a pair of outer side portions 17a7 of the connection terminal 17. The individual fixing portion 16f seals the corresponding protruding portion 17a3 formed around the outer edge of the corresponding depression 17a2 of the corresponding connection terminal 17 (the corresponding inner wiring portion 17a).

The individual fixing portion 16f includes a protruding portion 16g, a pressing portion 16h, and a sealing portion 16h1. As in the second embodiment, the individual protruding portion 16g and the individual pressing portion 16h are formed on one of the outer side portions 17a7 and one of the depressions 17a2 of the corresponding connection terminal 17 (the corresponding inner wiring portion 17a).

The individual sealing portion 16h1 is formed around the corresponding pressing portion 16h. In a sectional view in FIG. 17, the individual sealing portion 16h1 is a portion enclosed by a dotted line adjacent to the outside of the pressing portion 16h, and completely seals the corresponding protruding portion 17a3 of the connection terminal 17. The sealing portion 16h1 may seal the protruding portion 17a3, and may be in contact with the top surface 17a5 around the protruding portion 17a3. Sealing portions 16h1 may be formed on outer edges of the pressing portions 16h, the outer edges facing each other. However, a space needs to be left between these sealing portions 16h1 facing each other for the bonding of a bonding wire 20. The outer edge of the individual sealing portion 16h1 may have an arc-like shape in plan view. In addition, the outer surface of the individual sealing portion 16h1 may have a slope, as long as the corresponding protruding portion 17a3 is sealed. The lower end of the sloping outer surface of the sealing portion 16h1 is located inside the upper end of the sloping outer surface.

In addition, the upper end of the protruding portion 16g, the upper end of the pressing portion 16h, and the upper end of the sealing portion 16h1 of the individual fixing portion 16f may be on the same plane. For example, a group of concave and convex portions may be formed uniformly on the upper end of the individual fixing portion 16f. Alternatively, spire-like portions may be formed on the upper end of the fixing portion 16f. In addition, the individual fixing portion 16f may have a dome-like shape in side view, as long as the corresponding protruding portion 17a3 is sealed. In this case, the outer surface of the individual sealing portion 16h1 has a curved surface. When the fixing portion 16f is sealed by the sealing material 21, the area where the fixing portion 16f and the sealing material 21 are firmly attached to each other increases, and the adhesion is improved.

This semiconductor device 10 including the fixing portions 16f provides the same advantageous effects as those according to the second embodiment. In addition, because the fixing portions 16f seal the protruding portions 17a3, movement and misalignment of the connection terminals 17 (the inner wiring portions 17a) are reduced. Compared with the first embodiment, the movement of the connection terminals 17 (the inner wiring portions 17a) is further reduced. In addition, the adhesion of the sealing material 21 to the fixing portions 16f is greater than the adhesion to the connection terminals 17 (the inner wiring portions 17a). Thus, movement and misalignment of the connection terminals 17 (the inner wiring portions 17a) are further reduced.

The semiconductor device constructed as described above achieves reduction in extension of delamination of the sealing material in the case, and maintains its insulation.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip;
a wire electrically connected to the semiconductor chip;
a terminal having a top surface and a bottom surface opposite to each other, and a plurality of side surfaces between the top surface and the bottom surface, the terminal having, at one side of one end thereof,
a wire connection area on the top surface of the terminal, to which the wire is connected,
a terminal coupling portion having a step formed by one of the plurality of side surfaces and a flat surface that is parallel to the top surface of the terminal, to form a concave portion therein at a side of the top surface of the terminal, and
a protrusion on the top surface protruding in a direction away from the top surface and being located adjacent to the concave portion between the concave portion and the wire connection area;
a resin case that is in contact with the bottom surface of the terminal and has a case coupling portion coupled with the terminal coupling portion such that the case coupling portion is in contact with the one of the plurality of side surfaces and the concave portion of the terminal and extends upward along the terminal coupling portion to have a height above the protrusion of the terminal, the wire connection area, the concave portion and the protrusion being located inside the resin case; and
a sealing material sealing the case coupling portion and the wire connection area inside the resin case.

2. The semiconductor device according to claim 1, wherein
the plurality of side surfaces includes two opposing side surfaces opposite to each other in a terminal width direction of the terminal, and
the terminal coupling portion and the protrusion of the terminal are respectively provided two at respective ones of the two opposing side surfaces, each of the terminal coupling portions having the step formed by one of the two opposing side surfaces and the flat surface that is parallel to the top surface of the terminal, to form the concave portion therein.

3. The semiconductor device according to claim 2, wherein each of the concave portions has a semicircular shape in a plan view of the semiconductor device.

4. The semiconductor device according to claim 2, wherein the wire connection area is disposed between the protrusions at the two opposing side surfaces.

5. The semiconductor device according to claim 1, wherein the terminal coupling portion is a through-hole having the one of the plurality of side surfaces provided at a center of the terminal in a terminal width direction, and has the concave portion around the through-hole in a plan view of the semiconductor device.

6. The semiconductor device according to claim 1, wherein the protrusion is sealed by the sealing material.

7. The semiconductor device according to claim 1, wherein the protrusion is embedded in the case coupling portion.

8. The semiconductor device according to claim 1, wherein the concave portion has a circular shape in a plan view of the semiconductor device.

9. The semiconductor device according to claim 1, wherein the flat surface of the step of the concave portion is located midway between the top surface and the bottom surface of the terminal.

10. The semiconductor device according to claim 1, wherein the case coupling portion protrudes from the top surface of the terminal to have a height that is half of a thickness of the terminal.

11. The semiconductor device according to claim 1, wherein the terminal coupling portion further has another one of the plurality of side surfaces that has a slope.

12. The semiconductor device according to claim 1, wherein the terminal coupling portion further has another one of the plurality of side surfaces to form the concave portion that has another step.

13. The semiconductor device according to claim 1, wherein the terminal penetrates through the resin case and extends outside the resin case at another side thereof opposite to the one side of the one end of the terminal.

14. The semiconductor device according to claim 1, wherein
the terminal coupling portion further has another one of the plurality of side surfaces, and
the concave portion is formed by the flat surface, provided by offsetting the top surface of the terminal downward in a direction orthogonal to the top surface, and the another one of the plurality of side surfaces, provided by offsetting the one of the plurality of side surfaces outward in a direction orthogonal to the one of the plurality of side surfaces.
